(19) United States
(12) Patent Application Publication
(10) Pub. No.: US 2010/0270547 A1
(43) Pub. Date: Oct. 28, 2010

(54) SEMICONDUCTOR DEVICE

(75) Inventor: Doyeol Ahn, Seoul (KR)

Correspondence Address: Workman Nydegger;1000 Eagle Gate Tower, 60 East South Temple, Salt Lake City, UT, 84111, US

(73) Assignee: University of Seoul Industry Cooperation Foundation, Seoul (KR)

(21) Appl. No.: 12/430,424

(22) Filed: Apr. 27, 2009

(51) Int. Cl. H01L 29/26; H01L 29/12; H01L 21/20

(52) U.S. Cl. 257/43; 257/76; 438/104; 257/E29.079; 257/E29.068; 438/478; 257/E21.09

(57) ABSTRACT

Semiconductor devices having at least one barrier layer with a wide energy band gap are disclosed. In some embodiments, a semiconductor device includes at least one active layer composed of a first compound, and at least one barrier layer composed of a second compound and disposed on at least one surface of the at least one active layer. The at least one barrier layer may have a wider energy band gap than an energy band gap of the at least one active layer. The compositions of the first and second compounds may be controlled to adjust the difference between Fermi functions for conduction band and valence band in the at least one active layer.

### BACKGROUND

Group III-V compound and Group II-VI compound semiconductors have particularly wide band gaps and are capable of emitting green or blue light. Recently, semiconductor devices, such as photo-electric conversion devices using III-V or II-VI group compound semiconductor crystals as base materials have been developed to improve efficiency and life time of the semiconductor devices.

However, one drawback to Group III-V compound and Group II-VI compound semiconductors are their poor optical gain characteristics.

### SUMMARY

In one embodiment, a semiconductor device includes at least one active layer composed of a first compound, and at least one barrier layer composed of a second compound and disposed on at least one surface of the at least one active layer. The at least one barrier layer may have a wider energy band gap than an energy band gap of the at least one active layer. The compositions of the first and the second compounds may be controlled to adjust the difference between Fermi functions for conduction band and valence band in the at least one active layer.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

FIGS. 1(a) and (b) are schematic diagrams of an illustrative embodiment of a semiconductor device.

FIGS. 2(a) and (b) are schematic diagrams showing band gaps of the semiconductor devices of FIG. 1.

FIG. 3 is a schematic diagram of an illustrative embodiment of a III-V group compound semiconductor device.

FIG. 4 is a graph showing an internal polarization field as a function of In composition of the AlGaInN barrier layer shown in FIG. 3.

FIG. 5 is a graph showing the relationship between In composition of the InGaN active layer and In composition of the AlGaInN barrier layer shown in FIG. 3.

FIG. 6 is a graph showing quasi-Fermi level separation as a function of In composition of the InGaN active layer shown in FIG. 3.

FIG. 7 is a graph showing a peak optical gain (y-axis) of the InGaN/AlGaInN semiconductor device as a function of In composition of the InGaN active layer (x-axis) shown in FIG. 3.

FIG. 8 is a graph showing an optical gain as a function of a wavelength for the InGaN/AlGaInN semiconductor device shown in FIG. 3 and a InGaN/GaN semiconductor device.

FIG. 9 is a schematic diagram of an illustrative embodiment of a II-VI group compound semiconductor device.

FIG. 10 is a graph showing an internal polarization field as a function of Mg composition of the MgZnO barrier layer for different mole fractions of Cd composition of the CdZnO active layer shown in FIG. 9.

FIG. 11 shows graphs illustrating (a) the relationship between Mg composition of the MgZnO barrier layer and Cd composition of the CdZnO active layer shown in FIG. 9, and (b) a wavelength of the semiconductor device shown in FIG. 9 as a function of Cd composition of the CdZnO active layer shown in FIG. 9.

FIG. 12 shows graphs illustrating (a) an optical gain as a function of a wavelength for different mole fractions of Cd compositions of the CdZnO active layer shown in FIG. 9, and (b) an optical gain as a function of different mole fractions of Cd composition of the CdZnO active layer shown in FIG. 9.

FIGS. 13(a)-(e) are schematic diagrams illustrating an illustrative embodiment of a method for fabricating a semiconductor device.

### DETAILED DESCRIPTION

In one embodiment, a semiconductor device includes at least one active layer composed of a first compound, and at least one barrier layer composed of a second compound and disposed on at least one surface of the at least one active layer. An energy band gap of the at least one barrier layer may be wider than an energy band gap of the at least one active layer. The compositions of the first compound and the second compound may be controlled to adjust a difference between Fermi functions for conduction band and valence band in the at least one active layer.

The difference between Fermi Functions for conductive band and valence band in the at least one active layer can be inverse proportion to an internal polarization field in the at least one active layer. The compositions of the first and/or second compounds can be controlled to reduce the internal polarization field in the at least one active layer. Further, the compositions of the first and/or second compounds can be controlled to make a sum of piezoelectric and spontaneous polarizations in the at least one active layer and a sum of piezoelectric and spontaneous polarizations in the at least one barrier layer substantially the same to reduce the internal polarization field.

Each of the first and second compounds can include a III-V group compound semiconductor material or a II-VI group compound semiconductor material. By way of example, the first compound can include GaN, InGaN, CdZnO, AlN, AlP, AlAs, GaP, GaAs, InN, InP, InAs, AlGaN, AlGaP, AlGaAs, InGaN, InGaP, InGaAs, InAlN, InAlP, InAlAs, AlGaInN, AlGaInP, AlGaInAs, ZnO, ZnS, CdO, CdS, CdZnS, CdZnO, MgZnO, MgZnS, CdMgZnO, or CdMgZnS. By way of example, the second compound can include AlInGaN, InGaN, AlGaN, AlGaP, AlGaAs, InGaN, InGaP, InGaAs, INAlN, InAlP, InAlAs, AlGaInP, AlGaInAs, CdZnS, CdZnO, MgZnO, MgZnS, CdMgZnO, or CdMgZnS.

In some embodiments, the first compound can include InₓGa₁₋ₓN (0≦x≦1) and the second compound can include Al_{y1}Ga_{1-y1-y2}In_{y1}N (0≦y1+y2≦1). Variable x can be in the range of about 0.05 and 0.15, variable y1 can be in the range of about 0.05 to 0.3, and variable y2 can be in the range of about 0.1 and 0.22.

In some embodiments, the first compound can include CdₓZn₁₋ₓO (0≦x≦1) and the second compound can include Mg_{y}Zn_{1-y}O (0≦y≦1). Variable x can be in the range of about 0 and 0.20, and variable y can be in the range of about 0.01 and 0.80.

The at least one active layer can have a thickness of about 0.1 nm to 300 nm, and the at least one barrier layer can have a thickness of about 0.1 nm to 500 nm.

In some embodiments, the energy band gap of the at least one active layer can be in the range of about 0.7 eV and 3.4 eV, and the energy band gap of the at least one barrier layer can be in the range of about 3.5 eV and 6.3 eV. In other embodiments, the energy band gap of the at least one active layer can be in the range of about 2.2 eV and 3.35 eV, and the energy band gap of the at least one barrier layer can be in the range of about 3.36 eV and 5.3 eV.

An optical gain of the semiconductor device can be substantially identical to or greater than 14,000/cm.

In another embodiment, a method for fabricating a semiconductor device includes forming at least one active layer composed of a first compound on a substrate, forming at least one barrier layer composed of a second compound on at least one surface of the at least one active layer, and adjusting a difference between Fermi functions for conduction band and valence band in the at least one active layer by controlling compositions of the first compound and/or the second compound. An energy band gap of the at least one barrier layer can be wider than an energy band gap of the at least one active layer. The compositions of the first and/or second compounds can be adjusted to reduce an internal polarization field in the at least one active layer. Each of the first and second compounds can include III-V group compound semiconductor material or II-VI group compound semiconductor material.

In some embodiments, the first compound can include InₓGa₁₋ₓN and the second compound can include Al_{y1}Ga_{1-y1-y2}In_{y1}N. The compositions of the first and/or second compounds can be adjusted by controlling a variable x in the range of 0-1, and a sum of variables y1 and y2 in the range of 0-1. In other embodiments, the first compound can include CdₓZn₁₋ₓO and the second compound can include Mg_{y}Zn_{1-y}O. The compositions of the first and/or second compounds can be adjusted by controlling each of variables x and y in the range of about 0-1.

The at least one active layer and the at least one barrier layer can be formed by employing radio-frequency (RF) magnetron sputtering, pulsed laser deposition, metal organic chemical vapor deposition (MOCVD), molecular beam epitaxy or radio-frequency plasma-excited molecular beam epitaxy. The compositions of the first and/or second compounds can be adjusted by controlling an amount of precursor gases or by controlling a processing temperature or processing time to adjust the difference between the Fermi functions for conduction band and valence band in the at least one active layer.

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

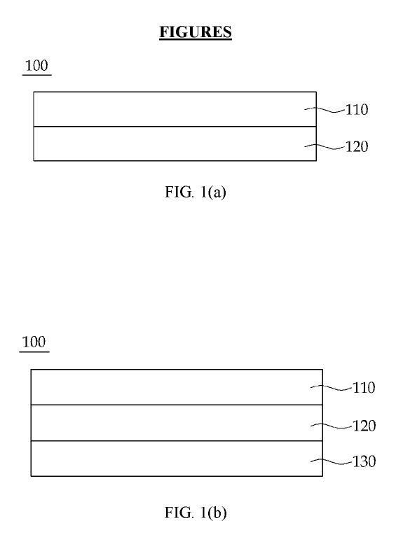

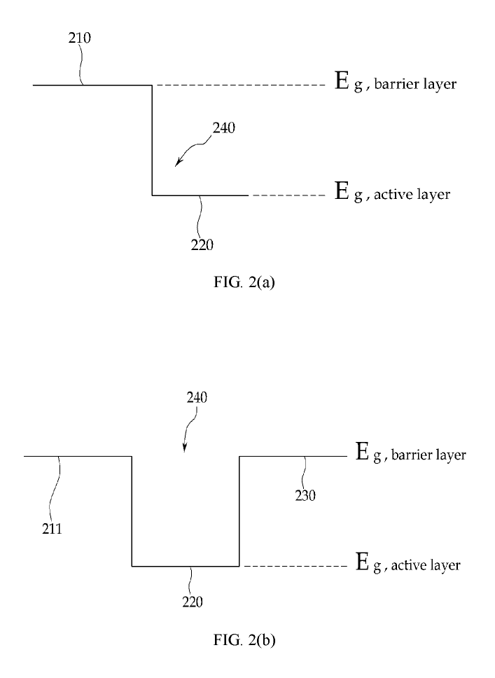

With reference to FIGS. 1 and 2, a semiconductor device in accordance with the present disclosure will now be described. FIGS. 1(a) and (b) are schematic diagrams of an illustrative embodiment of a semiconductor device 100. FIGS. 2(a) and (b) are schematic diagrams showing band gaps of semiconductor device 100.

As depicted in FIG. 1(a), semiconductor device 100 may have a single heterostructure in which a barrier layer 110 is disposed on one surface (e.g., a top surface) of an active layer 120. Barrier layer 110 has a wider band gap that is wider than the band gap of active layer 120. Accordingly, as depicted in FIG. 2(a), a band gap (E_{g,active layer}) 220 of active layer 120 is lower than a band gap (E_{g,barrier layer}) 210 of barrier layer 110, so that a quantum well 240 is formed in active layer 120. E_{g,active layer} is the difference between E_{c} and Eᵥ at active layer 120, and E_{g,barrier layer} is the difference between E_{c} and Eᵥ at barrier layer 110. E_{c} refers to an energy level at a conduction band of a semiconductor material, for example, a III-V group or a II-VI group compound semiconductor material. Eᵥ refers to an energy level at a valence band of a semiconductor material, for example, a III-V group or a II-VI group compound semiconductor material. Quantum well 240 is a thin layer which can confine carriers, such as electrons or holes, in a dimension perpendicular to a surface of the thin layer. Due to the band gap differences between active layer 120 and barrier layer 110, particles, such as electrons or holes can be confined in quantum well 240.

As depicted in FIG. 1(b), semiconductor device 100 may optionally have a second barrier layer (e.g., a barrier layer 130), and thus form a double heterostructure. For example, semiconductor device 100 may have active layer 120, barrier layer 110 disposed on one surface (e.g., a top surface) of active layer 120 and a barrier layer 130 disposed on the other surface (e.g., a bottom surface) of active layer 120. For the purpose of illustration, barrier layers 110 and 130 are hereinafter referred as upper barrier layer 110 and lower barrier layer 130. Each barrier layer 110 or 130 has a wider band gap than that of active layer 120. Quantum well 240 is also formed in active layer 120 because of the differences between band gap (E_{g,active layer}) 220 of active layer 120 and band gap (E_{g,upper barrier layer}) 210 of upper barrier layer 110 and a band gap (E_{g,lower barrier layer}) 230 of lower barrier layer 130, as depicted in FIG. 2(b).

Active layer 120 may be composed of a III-V group compound semiconductor material or a II-VI group compound semiconductor material. By way of example, III-V group semiconductor material includes, without limitation, GaN, InGaN, AlN, AlP, AlAs, GaP, GaAs, InN, InP, InAs, AlGaN, AlGaP, AlGaAs, InGaN, InGaP, InGaAs, INAlN, InAlP, InAlAs, AlGaInN, AlGaInP or AlGaInAs. The II-VI group semiconductor material includes, without limitation, ZnO, ZnS, CdO, CdS, CdZnO, CdZnS, MgZnO, MgZnS, CdMgZnO or CdMgZnS.

Each of upper and lower barrier layers 110 and 130 in FIG. 1 may be composed of a III-V group compound semiconductor material or a II-VI group compound semiconductor material. In some embodiments, each of upper and lower barrier layers 110 and 130 may also include a ternary compound semiconductor material or a quaternary compound semiconductor material. By way of example, each of barrier layers 110 and 130 may include a III-V group compound semiconductor material or a II-VI group compound semiconductor. The III-V group compound semiconductor material may include, without limitation, AlInGaN, InGaN, AlGaN, AlGaP, AlGaAs, InGaN, InGaP, InGaAs, InAlN, InAlP, InAlAs, AlGaInP or AlGaInAs. The II-VI group compound semiconductor material may include, without limitation, CdZnS, MgZnS, CdZnO, MgZnO, CdMgZnO or CdMgZnS.

In other embodiments, semiconductor device 100 can have two or more active layers and two or more barrier layers. For example, the two or more active layers and the two or more barrier layers can be sequentially deposited to form a sandwiched configuration in which an active layer is sandwiched with two barrier layers.

A quantum efficiency is a quantity defined as the percentage of photons that produces an electron-hole pair, and can be measured by, for example, an optical gain of semiconductor device 100. The optical gain g(ω) can be calculated by using a non-Markovian model with many-body effects due to interband transitions. The “many-body effects” refer to a band gap renormalization and an enhancement of optical gain due to attractive electron-hole interaction (Coulomb or excitonic enhancement). The optical gain g(ω) is given by Equation (1) as below. For theory on the optical gain, see Doyeol Ahn, “Theory of Non-Markovian Gain in Strained-Layer Quantum-Well Lasers with Many-Body Effects”, IEEE Journal of Quantum Electronics, Vol. 34, No. 2, p. 344-352 (1998), and Ahn et al., “Many-Body Optical Gain and Intraband Relaxation Time of Wurtzite InGaN/GaN Quantum-Well Lasers and Comparison with Experiment”, Appl. Phys. Lett. Vol. 87, p. 044103 (2005), which are incorporated by references herein in their entireties.

$$g ( ω ) = \frac{ω μ c}{{n}_{r} V} {\sum }_{σ η lm}^{ } {\sum }_{{\vec{k}}_{‖}}^{ } {\vert \hat{ɛ} \cdot {M}_{lm}^{η σ} ( {\vec{k}}_{‖} ) \vert}^{2} ( {f}_{c} - {f}_{h σ} ) {C}_{lm}^{η σ} ( {\vec{k}}_{‖} ) \qquad Equation ( 1 )$$

where ω is an angular frequency of photon in active layer 120; μ is a vacuum permeability; nᵣ is a refractive index of active layer 120; c is the speed of light in free space; V is the volume of active layer 120; f_{c} and f_{hσ} are Fermi functions for conduction band and valence band of 3×3 block Hamiltonian H^{σ}, respectively; Mₗₘ^{ησ}(\vec{k}_{∥}) is a dipole matrix element between the conduction band with a spin state η and the valence band of the 3×3 block Hamiltonian H^{σ}; \hat{∈} is an unit vector in the direction of the photon polarization; and Cₗₘ^{ησ}(\vec{k}_{∥}) is a renormalized lineshape function.

As shown in Equation (1) above, the optical gain g(ω) is proportional to the difference between Fermi functions for conduction band and valence band of the 3×3 block Hamiltonian H^{σ}, i.e. (f_{c}−f_{hσ}). The Fermi function difference (f_{c} . . . f_{hσ}) relates to the separation of a quasi-Fermi level at steady state. The quasi Fermi level describes a new Fermi level that each type of charge carriers, such as electrons and holes in a semiconductor appears to share when their populations are displaced from equilibrium. This displacement could be caused by the application of an electric potential, such as the electric potential caused by an internal polarization field existing in active layer 120. This displacement causes the Fermi function difference (f_{c}−f_{hσ}) to be decreased. Accordingly, the Fermi function difference (f_{c}−f_{hσ}) decreases as the internal polarization field increases. In turn, the term (f_{c}−f_{hσ}) in Equation (1) is enhanced when the internal polarization field is decreased.

The internal polarization field in quantum well 240 arises from spontaneous polarization P_{SP} and piezoelectric polarization P_{PZ}. Piezoelectric polarization P_{PZ} refers to polarization that arises from an electric potential generated in response to applied mechanical stress, such as strain of a layer. Spontaneous polarization P_{SP} refers to polarization that arises in ferroelectrics without an external electric field. Although P_{PZ} alone can be reduced by the reduction of the strain, P_{SP} still remains in quantum well 240. For additional detail on spontaneous and piezoelectric polarizations and the internal polarization field, see Ahn et al., “Spontaneous and piezoelectric polarization effects in wurtzite ZnO/MgZnO quantum well lasers”. Appl. Phys. Lett. Vol. 87, p. 253509 (2005), which is incorporated by reference herein in its entirety.

Thus, the quasi-Fermi level separation is increased and thus the optical gain g(ω) is increased, when a total internal polarization field, that includes spontaneous and piezoelectric polarizations P_{SP} and P_{SZ}, is reduced. The total internal polarization field F_{z}^{w} in quantum well 240 can be determined from the difference between the sum of P_{SP} and P_{PZ} in quantum well 240 and the sum of P_{SP} and P_{PZ} in upper barrier layer 110 and lower barrier layer 130 and be presented by Equation (2) below.

F_{Z}^{W}=[(P_{SP}^{b}+P_{PZ}^{b})−(P_{SP}^{w}+P_{PZ}^{w})]/(∈^{w}+∈^{b}L_{w}/L_{b}) Equation (2)

where P is the polarization, the superscript w and b denote quantum well 240 and upper and lower barrier layers 110 and 130 respectively, L is the thickness of quantum well 240 and upper and lower barrier layers 110 and 130, and E is a static dielectric constant.

Internal polarization field F_{z}^{w} can have a value of zero by making the sum (P_{SB}^{b}+P_{PZ}^{b}) of the spontaneous and piezoelectric polarizations at upper and lower barrier layers 110 and 130 and the sum (P_{SP}^{w}+J_{PZ}^{w}) of the spontaneous and piezoelectric polarizations at quantum well 240 the same. For example, this can be achieved by controlling the mole fractions of the compound in upper and lower barrier layers 110 and 130, and/or active layer 120.

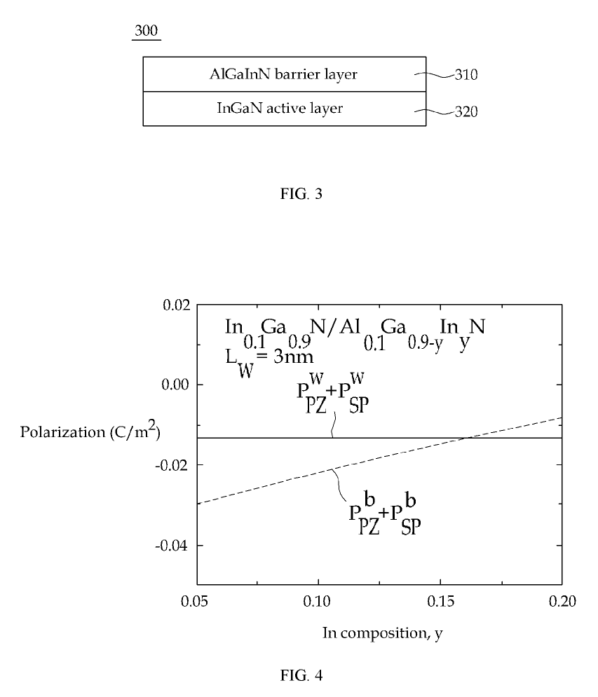

With reference to FIGS. 3 through 8, a III-V group compound semiconductor device having a minimized an internal polarization field will now be described. FIG. 3 is a schematic diagram of an illustrative embodiment of a III-V group compound semiconductor device. FIG. 4 is a graph showing internal polarization field as a function of indium (In) composition of the AlGaInN barrier layer depicted in FIG. 3.

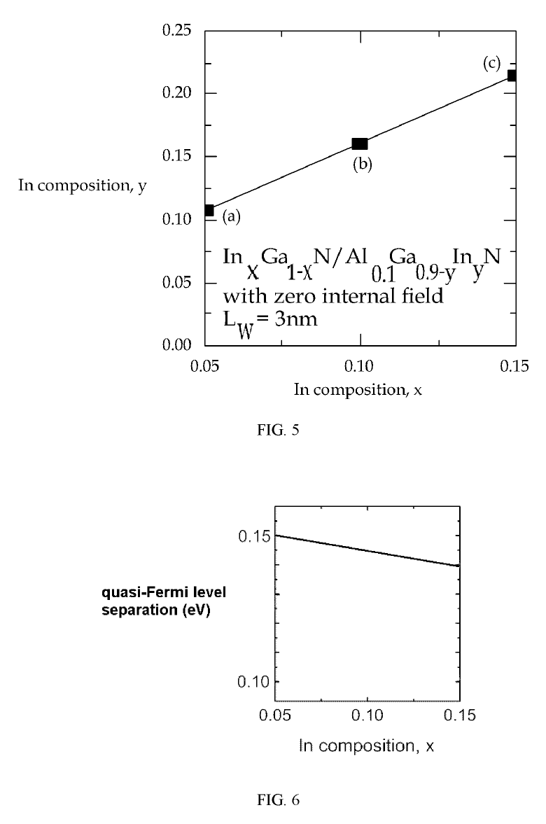

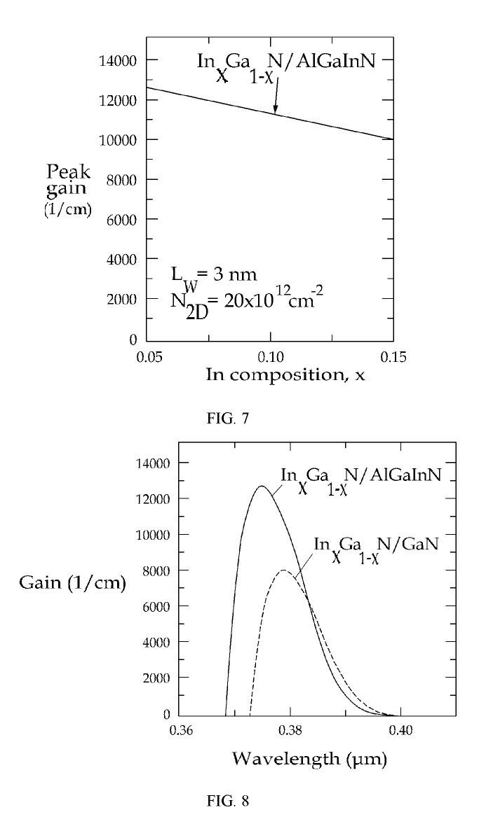

FIG. 5 is a graph showing the relationship between In composition of the InGaN active layer and In composition of the AlGaInN barrier layer depicted in FIG. 3. FIG. 6 is a graph showing quasi-Fermi level separation as a function of In composition of the InGaN active layer depicted in FIG. 3. FIG. 7 is a graph showing the peak optical gain (y-axis) of the InGaN/AlGaInN semiconductor device as a function of In composition of the InGaN active layer (x-axis) depicted in FIG. 3. FIG. 8 is a graph showing an optical gain as a function of a wavelength for the InGaN/AlGaInN semiconductor device depicted in FIG. 3 and a InGaN/GaN semiconductor device.

In some embodiments, as depicted in FIG. 3, a III-V group compound semiconductor device 300 includes an InGaN active layer 320 (i.e., an active layer composed of InGaN) and an AlGaInN barrier layer 310 (i.e. a barrier layer composed of AlGaInN) disposed on InGaN active layer 320. Alternatively, III-V group compound semiconductor device 300 may further have additional barrier layer disposed under one surface (e.g., bottom surface) of InGaN active layer 320. In some embodiments, InGaN active layer 320 has a thickness of several nanometers to several hundreds nanometers (nm). In other embodiments, InGaN active layer 320 can have a thickness of about 01 nm to 300 nm, or about 1 nm to 50 nm.

In some embodiments, AlGaInN Barrier layer 310 can have a thickness of several nanometers to several hundreds nanometers (nm). Alternatively, barrier layer 310 has a thickness of about 0.1 nm to 500 nm or about 1 nm and to 100 nm. In other embodiments, a III-V group compound semiconductor material having a band gap wider than a band gap of a III-V group compound semiconductor material of the active layer can be selected fro the barrier layer.

InGaN active layer 320 has a smaller band gap than the band gap of AlGaInN barrier layer 310, thus forming a quantum well in InGaN active layer 320. For example, the band gap of InGaN active layer 320 is in the range of about 0.7 eV and 3.4 eV, and the band gap of AlInGaN barrier layer 310 is in the range of about 0.7 eV and 6.3 eV. In some examples, the difference between the band gaps of InGaN active layer 320 and AlGaInN barrier layer 310 can be controlled by adjusting the composition of InGaN active layer 320, the composition of AlInGaN barrier layer 310, or the compositions of both InGaN active layer 320 and AlInGaN barrier layer 310. In an illustrative example, aluminum (Al) composition of AlInGaN barrier layer 310 can be controlled so that AlInGaN barrier layer 310 has a larger band gap than that of InGaN active layer 320. For example, the composition of AlInGaN barrier layer 310 can be controlled to achieve a mole fraction of Al composition in the range of about 0.05 to 0.3, assuming that the total mole value of a III group compound, that is, Al, In and Ga is one.

As illustrated with respect to Equation (2) above, an internal polarization field in a quantum well can be reduced by controlling the mole fractions of the compositions of InGaN active layer 320 and AlInGaN barrier layer 310, which will now be described in detail.

The graph shown in FIG. 4 illustrates the internal polarization field (y-axis) depending on the mole fraction of indium (In) composition (x-axis) of AlGaInN barrier layer 310. Here, InGaN active layer 320 is composed of In_{0.1}Ga_{0.9}N and has the thickness of 3 nm. AlGaInN barrier layer 310 is composed of Al_{0.1}Ga_{0.9-y}In_{y}N and has the thickness of about 3 nm to 15 nm. Variable y, which indicates the mole fraction of indium (In) composition of Al_{0.1}Ga_{0.9-y}In_{y}N barrier layer 310, may be controlled such that the sum P_{PZ}^{w}+P_{SP}^{w} of the piezoelectric and spontaneous polarizations in InGaN active layer 320 and the sum P_{PZ}^{b}+P_{SP}^{b} of the piezoelectric and spontaneous polarizations in AlGaInN barrier layer 310 are substantially the same. The cancellation of the sum of piezoelectric and spontaneous polarizations between a quantum well and AlGaInN barrier layer 310 makes a total internal polarization field in InGaN active layer 320 zero as defined in Equation (2).

As depicted in FIG. 5, the solid line indicates the sum (P_{PZ}^{w}+P_{SP}^{w}) of the piezoelectric and spontaneous polarizations in the quantum well. The dotted or dashed line indicates the sum (P_{PZ}^{b}+P_{SP}^{b}); of the piezoelectric and spontaneous polarizations in AlGaInN barrier layer 310. An experimental test showed that the solid line meets the dotted line when indium (In) composition (y) of Al_{0.1}Ga_{0.9-y}In_{y}N barrier layer 310 has a mole fraction of approximately 0.16. Because the sum P_{PZ}^{w}+P_{SP}^{w} and the sum P_{PZ}^{b}+P_{SP}^{b} are substantially the same at the point where the solid and dotted lines meet, the internal polarization field in InGaN active layer 320 becomes approximately zero according to Equation (2). Accordingly, when variable y is approximately 0.16, that is, AlGaInN barrier layer 310 has the composition of Al_{0.1}Ga_{0.74}In_{0.16}N, the internal polarization field becomes approximately zero. Through the minimization of the internal polarization field, quasi-Fermi separation can be largely enhanced and the optical gain g(ω) of semiconductor device 300 can be maximized in accordance with enhancement of quasi-Fermi separation, as illustrated above with respect to Equations (1).

Compositions of InGaN active layer 320 and AlGaInN barrier layer 310 can be controlled. The graph shown in FIG. 5 illustrates the relationship between In composition of InGaN active layer 320 (having the thickness of 3 nm) and In composition of AlGaInN barrier layer 310 (having the thickness of about 3 nm to 15 nm) when the internal polarization field is zero. As depicted in the graph of FIG. 5, an x-axis indicates the mole fraction of In composition of InGaN active layer 320, y-axis indicates the mole fraction of In composition of AlGaInN barrier layer 310, and the linear line indicates the points where the internal polarization field has a zero value.

As depicted in the graph of FIG. 5, the internal polarization field can be approximately zero when In compositions (variable x and y) of InGaN active layer 320 and AlGaInN barrier layer 310 are approximately 0.05 and 0.11 respectively (black square (a) on the linear line). In this case, InGaN active layer 320 has the composition of In_{0.05}Ga_{0.95}N and AlGaInN barrier layer 310 has the composition of Al_{0.1}Ga_{0.79}In_{0.11}N. Further, at the black square (b) on the linear line (that is, x and y are 0.1 and 0.16, respectively), semiconductor device 300 has In_{0.1}Ga_{0.9}N active layer and Al_{0.1}Ga_{0.74}In_{0.16}N barrier layer, and the internal polarization field becomes approximately zero. Still further, at the black square (c) on the linear line (that is, x and y are approximately 0.15 and 0.21, respectively), semiconductor device 300 has In_{0.15}Ga_{0.85}N active layer and Al_{0.1}Ga_{0.69}In_{0.21}N barrier layer, and the internal polarization field becomes approximately zero.

Accordingly, by using the linear line of the zero internal polarization field as shown in FIG. 5, In composition (y) of AlGaInN barrier layer 310 and/or In composition (x) of InGaN active layer 320 can be selected. In some embodiments, In composition (x) of InₓGa₁₋ₓN active layer 320 can be in the range of about zero (0) and 0.3, and In composition (y) of Al_{0.1}Ga_{0.9-y}In_{y}N barrier layer 310 can be in the range of about 0.01 and 0.3. In other embodiments, In composition (x) of InₓGa₁₋ₓN active layer 320 is in the range of about 0.05 and 0.15, and In composition (y) of Al_{0.1}Ga_{0.9-y}In_{y}N barrier layer 310 can be in the range of about 0.1 and 0.22. In some examples, In composition (x) of InₓGa₁₋ₓN active layer 320 is in the range of about 0.05 and 0.15, and In composition (y) of Al_{0.1}Ga_{0.9-y}In_{y}N barrier layer 310 can be in the range of about 0.1 and 0.22.

In some embodiments, the mole fractions of Al, Ga and In compositions of AlGaInN barrier layer 310 can be controlled to accomplish zero internal polarization field. For example, AlGaInN barrier layer 310 can have a composition of Al_{y1}Ga_{1-y1-y2}In_{y2}N (0≦y1+y2≦1). Variables y1 and y2 denote the mole fractions of Al and In compositions, respectively. A subtraction of y1 and y2 from one, that is, 1-y1-y2 denotes the mole fraction of Ga composition of Al_{y1}Ga_{1-y1-y2}In_{y2}N barrier layer 310. For example, y1 can be in the range of about 0.05 to 0.3, and y2 can be in the range of about 0.1 and 0.22, in order to accomplish the zero internal polarization field.

In some embodiments, the relationship between III-V group compound semiconductor materials of an active layer and a barrier layer can show non-linear relationship, such as logarithmic or exponential relationship in accordance with the type of the III-V group compound semiconductor materials of the active layer and barrier layer and the variety of compositions of the III-V group compound semiconductor materials.

In some examples, the mole fractions of In compositions of InGaN active layer 320 and AlGaInN barrier layer 310 can be selected in consideration of the compressive strain of InGaN active and AnGaInN barrier layers 420 and 410. Since the higher In composition (e.g., about 0.3 or more) of InGaN active layer 420 results in larger compressive strain and the growth of the strained layers is limited to a critical thickness, the lower In composition (e.g., about 0.01 to 0.1) can be selected.

As illustrated above, as the internal polarization field decreases, the quasi-Fermi level separation increases, that is, the difference between the Fermi functions for the conduction band and valence band, i.e., (f_{c}−f_{hσ}) increases. Accordingly, by controlling the compositions of an active layer and/or a barrier layer to reduce the internal polarization field, the quasi-Fermi level separation can be increased, and thus the optical gain g(ω) can be enhanced. The change of the quasi-Fermi level separation and optical gain for different compositions of the barrier layer is illustrated in FIGS. 6 and 7.

The graph shown in FIG. 6 illustrates the quasi-Fermi level separation (y-axis) for InGaN/AlGaInN semiconductor device 300 as a function of In composition of InGaN active layer (x-axis) 320. As shown in the graph, the quasi-Fermi level separation decreases as In composition of AlGaInN barrier layer 310 increases. For example, the total quasi-Fermi level separation is 0.15 when the mole fraction of In composition is 0.05. On the contrary, the quasi-Fermi level separation is 0.14 when the mole fraction of In composition is 0.15. Accordingly, it can be known that when In composition of AlGaInN barrier layer 310 is low, the quasi-Fermi level separation is high, thus the optical gain is high according to Equation (1). The change of the optical gain for different In compositions of AlGaInN barrier layer 310 is shown in FIG. 7.

The graph shown in FIG. 7 illustrates the peak optical gain (y-axis) of InGaN/AlGaInN semiconductor device 300 as a function of In composition of InGaN active layer (x-axis) 320. Here the carrier density in InGaN active layer 320 (N_{2D}), i.e. the number of carriers in InGaN active layer 320 per a square meter, is 20*10¹² cm⁻². As shown in the graph shown in FIG. 7, the peak optical gain increases as In composition of AlGaInN barrier layer 310 decreases. For example, the peak optical gain is approximately 12,600/cm when the mole fraction of In composition of InGaN active layer 320 is 0.05. On the contrary, the peak optical gain is approximately 10,000/cm when the mole fraction is 0.15. Accordingly, the optical gain can be enhanced by controlling the composition of InGaN active layer 320. This is also verified in another experimental result as illustrated in FIG. 8.

The graph shown in FIG. 8 illustrates the optical gain (y-axis) of InₓGa₁₋ₓN/AlGaInN semiconductor device 300 and a InₓGa₁₋ₓN/GaN semiconductor device as a function (x-axis) of wavelength. Assuming that variable x is 0.05, the peak optical gain of In_{0.5}Ga_{0.5}N/AlGaInN semiconductor device 300 is approximately 13,000/cm and the peak optical gain of the In_{0.5}Ga_{0.5}N/GaN semiconductor device is approximately 9,000/cm. The peak wavelength is shifted to shorter wavelength with the quaternary barrier layer. InGaN/AlGaInN semiconductor device 300 has much larger optical gain than that of the InGaN/GaN semiconductor device because the quasi-Fermi level separation in InGaN/AlGaInN semiconductor device 300 is largely enhanced due to disappearance of the internal field.

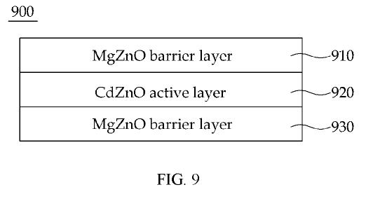

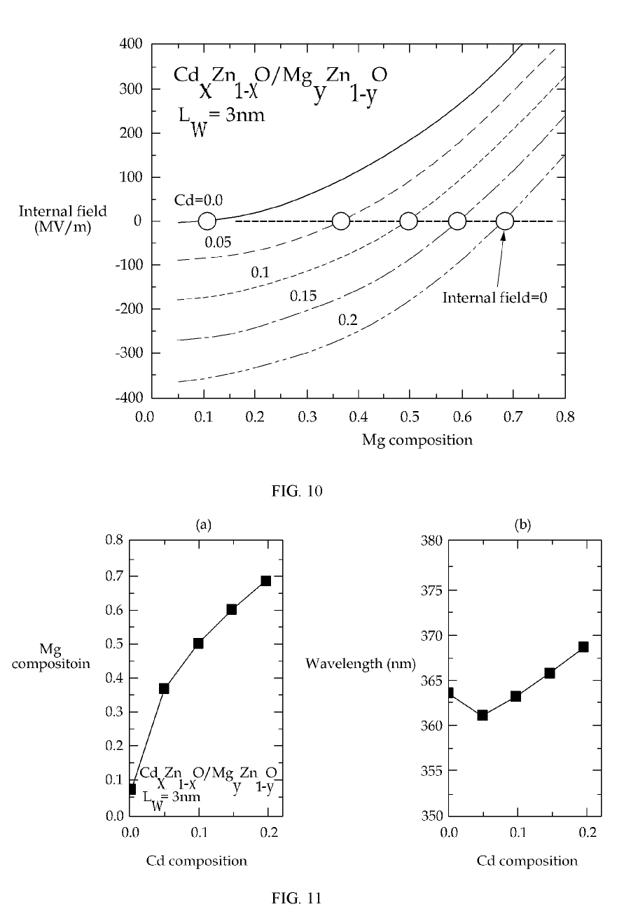

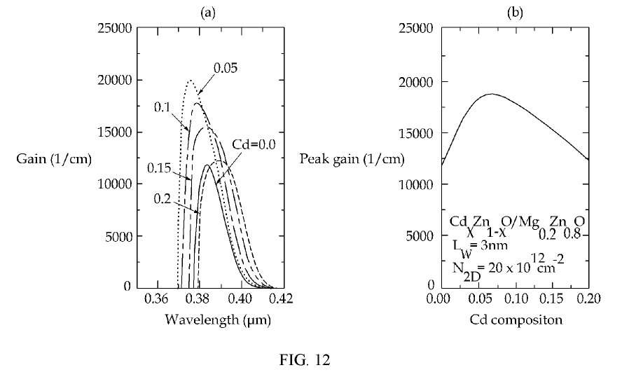

In another embodiment, a semiconductor device may have II-VI group compound. Such a II-VI group compound semiconductor device will be described with reference to FIGS. 9-12. FIG. 9 is a schematic diagram of an illustrative embodiment of a II-VI group compound semiconductor device. FIG. 10 is a graph showing an internal polarization field as a function of Mg composition of the MgZnO barrier layer for different Cd compositions of the CdZnO active layer depicted in FIG. 9. FIG. 11 shows graphs illustrating (a) the relationship between Mg composition of the MgZnO barrier layer and Cd composition of the CdZnO active layer depicted in FIG. 9 and (b) a wavelength of the semiconductor device as a function of Cd composition of the CdZnO active layer depicted in FIG. 9. FIG. 12 shows graphs illustrating (a) an optical gain as a function of a wavelength for different Cd compositions of the CdZnO active layer depicted in FIG. 9 and (b) a peak gain as a function of Cd compositions of the CdZnO active layer depicted in FIG. 9.

With reference to FIG. 9, a II-VI group compound semiconductor device 900 includes CdZnO active layer 920 (i.e. an active layer composed of CdZnO) and upper and lower MgZnO barrier layers 910 and 930 (i.e. upper and lower barrier layers each composed of MgZnO) disposed on opposite surfaces (e.g., top and bottom surfaces) of CdZnO active layer 920. In some embodiments, II-VI group compound semiconductor device 900 may have either upper or lower MgZnO barrier layer 910 or 930 disposed on one side (e.g. top surface or bottom surface) of active layer 920. In some embodiments, CdZnO active layer 920 is composed of a II-VI group compound semiconductor material, for example, ZnO, ZnS, CdO, CdS, CdZnO, CdZnS, MgznO, MgZnS, CdMgZnO or CdMgZnS. CdZnO active layer 920 may have a thickness of several nanometers to several hundreds nanometers. In other embodiments, the thickness of CdZnO active layer 920 may be about 0.1 nm to 300 nm, or about 1 nm to 50 nm.

In some embodiments, upper and lower MgZnO barrier layers 910 and 930 each have a thickness of several nanometers to several hundreds nanometers. In other embodiments, upper and lower MgZnO barrier layers 910 and 930 may each have a thickness of about 0.1 nm to 500 nm or about 1 nm and to 100 nm. The II-VI group compound semiconductor material of the upper and lower barrier layers (e.g., upper and lower MgZnO barrier layers 910 and 930) have wider band gaps than that of the II-VI group compound semiconductor material of the active layer (e.g., CdZnO active layer 920), thus forming a quantum well in the active layer (e.g., CdZnO active layer 920). In other embodiments, a II-VI group compound semiconductor material having a wider band gap than that of a II-VI group semiconductor material of the active layer can be selected for the upper an lower barrier layers.

In some embodiments, CdZnO active layer 920 has a band gap of about 2.2 eV to 3.35 eV, and upper and lower MgZnO barrier layers 910 and 930 each have a band gap of about 3.35 eV to 5.3 eV. The band gaps of upper and lower MgZnO barrier layers 910 and 930 and CdZnO active layer 920 can vary depending on the compositions of Mg, Zn or Cd. Thus, due to the differences between the band gaps of CdZnO active layer 920 and upper and lower MgZnO barrier layers 910 and 930, a quantum well is formed in CdZnO active layer 920. As illustrated with respect to Equation (2) above, the internal polarization field in the quantum well can be reduced by controlling the mole fractions of the compositions of CdZnO active layer 920 and upper and lower MgZnO barrier layers 910 and 930.

With reference to the graph shown in FIG. 10, the internal polarization field (y-axis) in CdZnO active layer 920 for different Cd compositions and Mg compositions (x-axis) will now be described. Here, assume that CdZnO active layer 920 has a composition of CdₓZn₁₋ₓO (0≦x≦1) and a thickness of about 3 nm, and upper and lower MgZnO barrier layers 910 and 930 have the composition of Mg_{y}Zn_{1-y}O (0≦y≦1) and have the thickness of about 3 nm to 15 nm. As illustrated for III-V group compound semiconductor 300 with respect to FIG. 4 above, the compositions of CdₓZn₁₋ₓO active layer 920 and upper and lower Mg_{y}Zn_{1-y}O barrier layers 910 and 930 can be controlled to make the internal polarization field in CdZnO active layer 920 approximately zero. This will result in the enhancement of the quasi-Fermi level separation in CdₓZn₁₋ₓO active layer 920.

As an example, when Cd composition of CdₓZn₁₋ₓO active layer 920 and Mg composition of upper and lower Mg_{y}Zn_{1-y}O barrier layers 910 and 930 are approximately zero and 0.1, respectively, that is, II-VI group compound semiconductor device 900 has active/barrier layers of ZnO/Mg_{0.1}Zn_{0.90}, the internal polarization field becomes zero. As another example, the internal polarization field becomes zero when variables x and y are approximately 0.05 and 0.37, 0.1 and 0.5, 0.15 and 0.6, and 0.2 and 0.7, respectively. In the case where variables x and y are 0.2 and 0.7, respectively, II-VI group compound semiconductor device 900 has active/barrier layers of Cd_{0.2}Zn_{0.80}/Mg_{0.7}Zn_{0.30}. When Cd composition (x) of CdₓZn₁₋ₓO active layer 920 is in the range of about zero (0) and 0.2, Mg composition (y) of Mg_{y}Zn_{1-y}O barrier layers 910 and 930 can be in the range of about 0.01 and 0.8.

The relationship between Mg and Cd compositions is illustrated in graph (a) of FIG. 11. In graph (a), the solid line indicates when the internal polarization field is zero. As illustrated in graph (a), Mg composition of upper and lower Mg_{y}Zn_{1-y}O barrier layers 910 and 930 can increase logarithmically in accordance with the increase of Cd composition of CdₓZn₁₋ₓO active layer 920 in the condition of zero internal polarization field. In this case, Mg composition of upper and lower Mg_{y}Zn_{1-y}O barrier layers 910 and 930 and Cd composition of CdₓZn₁₋ₓO active layer 920 are in a logarithmic relationship.

In some embodiments, the relationship between II-VI group compound semiconductor materials of a barrier layer and an active layer at a zero internal polarization field can be inverse proportional or exponential depending on the type of the II-VI group compound semiconductor materials of the layers or various compositions of the II-VI group compound semiconductor materials. In some embodiments, a relationship between the II-VI group compound semiconductor materials of the barrier layer and the active layer at the zero internal polarization field can be linear depending on a type of the II-VI group compound semiconductor materials and compositions of the II-VI group compound semiconductor materials.

Graph (b) in FIG. 11 illustrates a transition wavelength of II-VI group compound semiconductor device 900 as a function of Cd composition of CdZnO active layer 920. As illustrated in graph (b), the transition wavelength of II-VI group compound semiconductor device 900 can be changed by controlling Cd composition of CdZnO active layer 920. Therefore, Cd composition is selected in accordance with a desirable transition wavelength for various optoelectronic devices. Further, Mg composition can be selected depending on the selected Cd composition to have substantially the zero internal polarization field in CdZnO active layer 920.

Graph (a) in FIG. 12 illustrates an optical gain (y-axis) of CdₓZn₁₋ₓO/Mg_{0.2}Zn_{0.80} semiconductor device for different Cd compositions, as a function of the transition wavelength (x-axis). As illustrated in graph (a), the optical gain is correlated to Cd composition. That is, the optical gain can be changed by controlling Cd composition of CdₓZn₁₋ₓO active layer 920. As Cd composition of CdₓZn₁₋ₓO active layer 920 changes, the optical gain and the transition wavelength varies. As can be seen in graph (a), when the mole fraction of Cd composition changes from zero to 0.05, the transition wavelength of II-VI group compound semiconductor device 900 is shifted to the left, that is, peak wavelength of II-VI group compound semiconductor device 900 is reduced, and the optical gain of II-VI group compound semiconductor device 900 increases. As an example, when the mole fraction of Cd composition is approximately zero, the peak wavelength is approximately 0.385 μm and the optical gain in the peak wavelength is approximately 12,500/cm. As another example, when the mole fraction of Cd composition is 0.05, the peak of the transition wavelength of II-VI group compound semiconductor device 900 is approximately 0.375 and the optical gain of II-VI group compound semiconductor device 900 is approximately 20,000/cm. Accordingly, the optical gain of II-VI group compound semiconductor device 900 can be enhanced by controlling the mole fraction of Cd composition of CdₓZn₁₋ₓO active layer 920.

Graph (b) in FIG. 12 illustrates a peak gain (y-axis) of CdₓZn₁₋ₓO/Mg_{0.2}Zn_{0.8}O semiconductor device as a function of Cd composition (x-axis) of CdₓZn₁₋ₓO active layer 920. Here a thickness of CdₓZn₁₋ₓO active layer 920 is about 3 nm, and a carrier density (N_{2D}) in CdₓZn₁₋ₓO active layer 920, i.e. the number of carriers in CdₓZn₁₋ₓO active layer 920 per a square meter, is about 20*10¹² cm⁻². As illustrated in graph (b), the peak gain of II-VI group compound semiconductor device 900 can be changed for different Cd compositions. For example, II-VI group compound semiconductor device 900 can have the optical gain of approximately more than 17,000/cm when the mole fraction of Cd composition of CdₓZn₁₋ₓO active layer 920 is approximately 0.07.

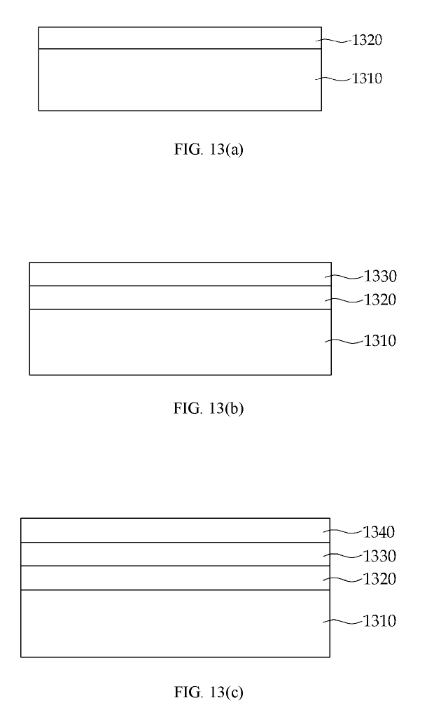

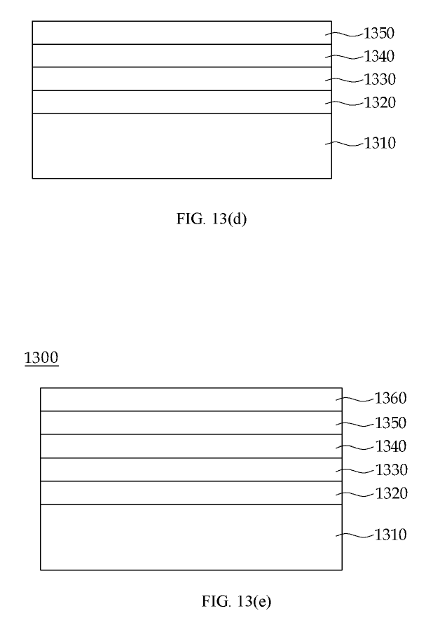

In some embodiments, a method for fabricating a semiconductor device is provided. FIGS. 13(a)-(e) are schematic diagrams illustrating an illustrative embodiment of a method for fabricating a semiconductor device 1300.

As depicted in FIG. 13(a), a substrate 1310 is provided. Substrate 1310 may be composed of a C-face (0001) or A-face (1120) oriented sapphire (Al₂O₃). Alternatively, substrate 1310 may include silicon (Si), silicon carbide (SiC), spinel (MgAl₂O₄), aluminum nitride (AlN), gallium nitride (GaN), or aluminum gallium nitride (AlGaN) without limitation. A buffer layer 1320 can be optionally disposed on one surface (e.g. a top surface) of substrate 1310. Buffer layer 1320 can be made of a III-V group compound semiconductor material or a II-VI group compound semiconductor material. The material for buffer layer 1320 is not limited to aforementioned III-V and II-VI groups, but may also include any material that establishes good structural quality. Buffer layer 1320 can have a thickness of from about 0.1 μm to 300 μm.

A lower barrier layer 1330 may be disposed on a top surface of buffer layer 1320, as depicted in FIG. 13(b). Lower barrier layer 1330 can include a III-V group compound semiconductor material or a II-VI group compound semiconductor material. Suitable materials and thickness for lower barrier layer 1330 are substantially the same as the materials and thickness described above for lower barrier layer 110. Lower barrier layer 1330 can be formed by using any deposition techniques known in the art, such as radio-frequency (RF) magnetron sputtering, pulsed laser deposition, metal organic chemical vapor deposition (MOCVD), molecular beam epitaxy, and radio-frequency plasma-excited molecular beam epitaxy, without limitation. The composition of lower barrier layer 1330 can be adjusted by controlling an amount of precursor gases provided to a deposition device (e.g. MOCVD) or by controlling a processing temperature or processing time.

As depicted in FIG. 13(c), an active layer 1340 is disposed over lower barrier layer 1330. Active layer 1340 can include a III-V group compound semiconductor material or a II-VI group compound semiconductor material. Suitable materials and thickness for active layer 1340 are substantially the same as the materials and thickness described above for active layer 120. Active layer 1340 can be formed by using any of the aforementioned deposition techniques known in the art.

In some embodiments, an upper barrier layer 1350 can be disposed on a top surface of active layer 1330, as depicted in FIG. 13(d). Upper barrier layer 1350 can be composed of the same material as lower barrier layer 1330. For example, upper barrier layer 1350 can include a III-V group compound semiconductor material or a II-VI group compound semiconductor material. Suitable materials and thickness for upper barrier layer 1350 are substantially the same as the materials and thickness described above for lower barrier layer 110. Upper barrier layer 1350 can be formed by using any of the aforementioned deposition techniques known in the art.

In some embodiments, lower barrier layer 1330 or upper barrier layer 1350 can be selectively disposed on active layer 1330. For example, semiconductor device 1300 can have lower barrier layer 1330 disposed on a bottom surface of active layer 1340, upper barrier layer 1350 disposed on a top surface of active layer 1340, or both lower and upper barrier layers 1330 and 1350 disposed on bottom and top surfaces of active layer 1340, respectively.

As described above, the III-V group compound semiconductor materials or the II-VI group compound semiconductor materials for active layer 1340 and/or upper and lower barrier layers 1350 and 1330 can be selected such that active layer 1340 has a narrower band gap than that of upper and lower barrier layers 1350 and 1330. This band gap difference forms a quantum well in active layer 1340.

As depicted in FIG. 13(e), an Electrode 1360 can be optionally disposed on a top surface of upper barrier layer 1350. Electrode 1360 can include conductive material such as an n-type doped semiconductor material, a p-type doped semiconductor material, or a metal. For example, Electrode 1360 can include, without limitation, Al, Ti, Ni, Au, Ti/Al, Ni/Au, Ti/Al/Ti/Au, or an alloy thereof. Electrode 1360 can be formed to have a thickness of about 1 nm to 300 nm, or about 5 nm to 50 nm. Electrode 1360 may be formed by using any techniques known in the art, such as sputtering, electroplating, e-beam evaporation, thermal evaporation, laser-induced evaporation, and ion-beam induced evaporation, without limitation.

Accordingly, a II-VI or III-V group compound semiconductor device in accordance with one embodiment can an reduce internal polarization field in a quantum well by forming an upper and/or lower barrier layer of II-VI group compound on at least one active layer of II-VI group compound, or forming an upper and/or lower barrier layer of III-V group compound on at least one active layer of III-V group compound. Further, the II-VI or III-V group compound semiconductor device can reduce the internal polarization field in the quantum well by controlling the mole fractions of a II-VI group compound or III-V group compound in the active layer, the upper barrier layer, and/or the lower barrier layer. Through the reduction of the internal polarization field in the quantum well, quasi-Fermi separation in the active layer can be largely enhanced and the optical gain of the semiconductor device is maximized.

In further example of the present disclosure, a photo-electric conversion device, an optoelectronic device, or a quantized electronic device in which the semiconductor device described above is installed can be provided. For example, a short wavelength emitter, a photo detector, a laser, a high electron mobility transistor, or a light emitting device can include a semiconductor device. The semiconductor device includes at least one active layer and at least one barrier layer disposed on at least one surface of the active layer. Each of the active layer and the barrier layer is composed of a III-V or II-VI group compound semiconductor material. The barrier layer has a wider band gap than that of the active layer.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes, but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A semiconductor device comprising:
at least one active layer composed of a first compound; and
at least one barrier layer composed of a second compound and disposed on at least one surface of the at least one active layer,
wherein an energy band gap of the at least one barrier layer is wider than an energy band gap of the at least one active layer, and
wherein compositions of the first compound and the second compound are controlled to adjust a difference between Fermi functions for conduction band and valence band in the at least one active layer.

2. The semiconductor device of claim 1, wherein the difference is increased as an internal polarization field in the at least one active layer is reduced, and wherein the compositions of the first and/or second compounds are controlled to reduce the internal polarization field in the at least one active layer.

3. The semiconductor device of claim 2, wherein the compositions of the first and/or second compounds are further controlled to make a sum of piezoelectric and spontaneous polarizations in the at least one active layer and a sum of piezoelectric and spontaneous polarizations in the at least one barrier layer substantially the same to reduce the internal polarization field.

4. The semiconductor device of claim 1, wherein each of the first and the second compounds comprises III-V group compound semiconductor or II-VI group compound semiconductor.

5. The semiconductor device of claim 1, wherein the first compound comprises GaN, InGaN, CdZnO, AlN, AlP, AlAs, GaP, GaAs, InN, InP, InAs, AlGaN. AlGaP, AlGaAs, InGaN, InGaP, InGaAs, INAlN, InAlP, InAlAs, AlGaInN, AlGaInP, AlGaInAs, ZnO, ZnS, CdO, CdS, CdZnS, CdZnO, MgZnO, MgZnS, CdMgZnO or CdMgZnS.

6. The semiconductor device of claim 1, wherein the second compound comprises AlInGaN, InGaN, AlGaN, AlGaP, AlGaAs, InGaN, InGaP, InGaAs, INAlN, InAlP, InAlAs, AlGaInP, AlGaInAs, CdZnS, CdZnO, MgZnO, MgZnS, CdMgZnO or CdMgZnS.

7. The semiconductor device of claim 1, wherein the first compound comprises InₓGa₁₋ₓN (0≦x≦1) and the second compound comprises Al_{y1}Ga_{1-y1-y2}In_{y1}N (0≦y1+y2≦1).

8. The semiconductor device of claim 7, wherein x is in the range of about 0.05 and 0.15, y1 is in the range of about 0.05 to 0.3, and y2 is in the range of about 0.1 and 0.22.

9. The semiconductor device of claim 1, wherein the first compound comprises CdₓZn₁₋ₓO (0≦x≦1), and the second compound comprises Mg_{y}Zn_{1-y}O (0≦y≦1).

10. The semiconductor device of claim 9, wherein x is in the range of about 0 and 0.20, and y is in the range of about 0.01 and 0.80.

11. The semiconductor device of claim 1, wherein the at least one active layer has a thickness of about 0.1 nm to 300 nm, and the at least one barrier layer has a thickness of about 0.1 nm to 500 nm.

12. The semiconductor device of claim 1, wherein the energy band gap of the at least one active layer is in range of about 0.7 and 3.4 eV, and the energy band gap of the at least one barrier layer is in range of about 0.7 and 6.3 eV.

13. The semiconductor device of claim 1, wherein the energy band gap of the at least one active layer is in range of about 2.2 and 3.35 eV, and the energy band gap of the at least one barrier layer is in range of about 3.35 and 5.3 eV.

14. The semiconductor device of claim 1, wherein an optical gain of the semiconductor device is substantially identical to or greater than 14,000/cm.

15. A method for fabricating a semiconductor device comprising:
forming at least one active layer composed of a first compound on a substrate;
forming at least one barrier layer on at least one surface of the at least one active layer, the at least one barrier layer composed of a second compound; and
adjusting a difference between Fermi functions for conduction band and valence band in the at least one active layer by controlling compositions of the first compound and/or the second compound,
wherein an energy band gap of the at least one barrier layer can be wider than an energy band gap of the at least one active layer.

16. The method of claim 15, wherein the compositions of the first and/or second compounds are adjusted to reduce an internal polarization field in the at least one active layer.

17. The method of claim 16, wherein each of the first and the second compounds comprises III-V group compound semiconductor or II-VI group compound semiconductor.

18. The method of claim 15, wherein when the first compound comprises InₓGa₁₋ₓN and the second compound comprises Al_{y1}Ga_{1-y1-y2}In_{y1}N, the adjusting of the compositions of the first and/or second compounds comprises controlling a variable x in the range of 0-1, and a sum of variables y1 and y2 in the range of 0-1.

19. The method of claim 15, wherein the first compound comprises CdₓZn₁₋ₓO and the second compound comprises Mg_{y}Zn_{1-y}O, and the adjusting of the compositions of the first and/or second compounds comprises controlling each of variables x and y in the range of about 0-1.

20. The method of claim 15, wherein the at least one active layer has a thickness of about 0.1 nm to 300 nm, and the at least one barrier layer has a thickness of about 0.1 nm to 500 nm.

21. The method of claim 15, wherein either forming the at least one active layer or forming the at least one barrier layer comprises employing radio-frequency (RF) magnetron sputtering, pulsed laser deposition, metal organic chemical vapor deposition (MOCVD), molecular beam epitaxy, or radio-frequency plasma-excited molecular beam epitaxy.

22. The method of 21, wherein the compositions of the first and/or second compounds are adjusted by controlling an amount of precursor gases or by controlling a processing temperature or processing time to adjust the difference.
